(19) United States
(12) Patent Application Publication
(10) Pub. No.: US 2012/0049912 A1
(43) Pub. Date: Mar. 1, 2012

(54) DIGITAL PHASE DIFFERENCE DETECTOR AND FREQUENCY SYNTHESIZER INCLUDING THE SAME

(75) Inventors: Seiichiro Yoshida, Osaka (JP); Atsushi Ohara, Shiga (JP)

(73) Assignee: PANASONIC CORPORATION, Osaka (JP)

(21) Appl. No.: 13/289,707

(22) Filed: Nov. 4, 2011

Related U.S. Application Data
(63) Continuation of application No. PCT/JP2010/006331, filed on Oct. 26, 2010.

(30) Foreign Application Priority Data
Jun. 21, 2010 (JP) 2010-140479

(51) Int. Cl. H03L 7/08

(52) U.S. Cl. 327/156

(57) ABSTRACT

A digital phase difference detector detects a phase difference between first and second signals. A delay circuit cumulatively delays the first signal. A flip flop group latches the signals. An edge detector detects a first phase difference between a rise of the first signal and either one of a rise or a fall of the second signal, and a second phase difference between a fall of the first signal and either one of the rise or the fall of the second signal. A memory circuit stores the phase differences. A normalization circuit computes a cycle of the first signal from a difference between previous first and second phase differences stored in the memory circuit and a difference between the first and second phase differences which are currently detected by the edge detector to normalize the phase difference between the first and second signals with reference to the cycle.

### CROSS-REFERENCE TO RELATED APPLICATION

This is a continuation of PCT International Application PCT/JP2010/006331 filed on Oct. 26, 2010, which claims priority to Japanese Patent Application No. 2010-140479 filed on Jun. 21, 2010. The disclosures of these applications including the specifications, the drawings, and the claims are hereby incorporated by reference in their entirety.

### BACKGROUND

The present disclosure relates to digital phase difference detectors for converting a phase difference between two signals to a digital value, and outputting the digital value, and relates to frequency synthesizers including the same.

In recent years, along with progress in CMOS microfabrication technology, studies have been pursued in attempt to achieve, for example, low voltage operation, reduced variations in characteristics, reduced circuit size by replacing all or some of analog circuits with digital circuits. For example, there is an all-digital PLL frequency synthesizer whose components such as a phase comparator and a loop filter are all digitized. The synthesizer includes, instead of a voltage-controlled oscillator whose frequency is control by an analogue voltage, a digitally controlled oscillator (DCO) whose frequency can be controlled by discrete numerical information (digital value), wherein phase information of an oscillation frequency signal output from the digitally controlled oscillator is digitized and fed back to the digitally controlled oscillator via the phase comparator and the loop filter, thereby implementing a phase-locked loop.

In order to improve comparison precision, the all-digital PLL frequency synthesizer may further include a digital phase difference detector which detects a phase difference between a reference frequency signal and the oscillation frequency signal. The digital phase difference detector serves as a device to measure a subtle phase difference or a subtle time difference between two signals, and is applicable not only to synthesizers but also to various technical fields.

Generally, a digital phase difference detector used in an all-digital PLL frequency synthesizer, and the like includes a time-to-digital converter (TDC) which converts a phase difference between two signals to a digital value, and a normalization circuit which normalizes the detected phase difference. The time-to-digital converter cumulatively delays a reference frequency signal FREF by a delay circuit to generate signals having respective delay amounts, and detects, based on logical levels of the signals having the respective delay amounts at the rise of an oscillation frequency signal CKV, a phase difference Δtr between the rise of CKV and the rise of FREF, and a phase difference Δtf between the fall of CKV and the rise of FREF. Δtr and Δtf are each a quantized value obtained by division by a delay time per delay element of the delay circuit. The normalization circuit computes the cycle of CKV from Δtf and Δtr, and computes a phase difference ε obtained by normalizing the phase difference between FREF and CKV based on the computed cycle. The phase difference ε is computed as follows. When CKV is at the H level at the rise of FREF (positive phase error, see FIG. 9A), ε=Δtr/2(Δtf−Δtr), and when CKV is at the L level at the rise of FREF (negative phase error, see FIG. 9B), ε=Δtr/2(Δtr−Δtf) (see, for example, Japanese Patent Publication No. 2002-076886).

The phase difference ε represents the ratio of a rise phase difference between FREF and CKV to the cycle of CKV. That is, ε is defined as: ε=(rise phase difference between FREF and CKV)/(cycle of CKV). In a conventional technique, the maximum delay amount of the delay circuit is limited to one cycle of CKV in order to reduce the number of stages of delay elements included in the delay circuit as much as possible. Thus, a high period or a low period of CKV is computed from Δtf and Δtr, and the obtained period is doubled to compute the cycle of CKV for convenience. However, this computation is performed on condition that CKV has a duty ratio of 50%. This may cause a problem. For example, the computed duty ratio of CKV may be deviated from 50% depending on delay circuits, and in this case, ε may be different from a true value.

Moreover, since propagation delay characteristics respectively of the rise and the fall of CKV are different from each other, unit delay time in which the rise of CKV propagates through the delay circuit differs from unit delay time in which the fall of CKV propagates through the delay circuit. As a result, the computed duty ratio of CKV deviates from 50%, and ε differs from the true value. As described above, since the ε computation precision of the conventional digital phase difference detector is not very high, highly precise phase comparison cannot be performed in an PLL, and the like which may degrade noise characteristics of the oscillation frequency signal.

In order to equalize computation results of ε to improve the precision of ε both in the positive phase error and the negative phase error, the high period or the low period of CKV is not doubled to compute the cycle of CKV, but directly detecting the cycle of CKV is effective in both the errors. That is, as illustrated in FIG. 10, it is preferable to detect a phase difference Δtr2 between the rise of CKV in an immediately preceding cycle and the rise of FREF and a phase difference Δtf2 between the fall of CKV in the immediately preceding cycle and the rise of FREF, and to directly detect the cycle of CKV from the subtraction Δtr2−Δtr (in the case of the positive phase error) or Δtf2−Δtf (in the case of the negative phase error).

However, when it is attempted to directly detect the cycle of CKV, the delay circuit has to be capable of outputting CKV with a delay amount which is 1.5 times as large as the cycle of CKV. Thus, the number of delay elements which have to be provided in the delay circuit increases by 1.5 times, thereby increasing the circuit area and power consumption. As described above, there is a trade-off relationship between improving the precision of ε and a reduction in circuit area and power consumption.

### SUMMARY

The present invention may be advantageous for improving the precision, reducing the circuit area, and reducing the power consumption of a digital phase difference detector and a frequency synthesizer including the same.

An example digital phase difference detector for detecting a phase difference between a first signal and a second signal includes: a delay circuit configured to cumulatively delay the first signal to generate signals having respective delay amounts; a flip flop group configured to latch the signals having the respective delay amounts in synchronization with the second signal; an edge detector configured to detect, from an output of the flip flop group, a first phase difference between a rise of the first signal and either one of a rise or a fall of the second signal, and a second phase difference between a fall of the first signal and either one of the rise or the fall of the second signal; a memory circuit configured to store the first phase difference and the second phase difference; and a normalization circuit configured to compute a cycle of the first signal from a difference between a previous first phase difference and a previous second phase difference which have been stored in the memory circuit and a difference between the first phase difference and the second phase difference which are currently detected by the edge detector to normalize the phase difference between the first signal and the second signal with reference to the cycle. Moreover, an example frequency synthesizer for generating an oscillation frequency signal having a frequency which is a multiple of a frequency command word from a reference frequency signal includes the digital phase difference detector described above as a phase difference comparator between the reference frequency signal and the oscillation frequency signal.

With this configuration, one of a high period or a low period of the first signal is computed from the difference between the previous first phase difference and the previous second phase difference which have been stored in the memory circuit and the other one of the high period or the low period is computed from the difference between the first phase difference and the second phase difference which are currently detected by the edge detector. Thus, phase difference detection precision equal to the precision of when one cycle of the first signal is directly detected can be achieved with maximum delay required for the delay circuit being limited to one cycle of the first signal.

Note that the memory circuit may store the difference between the first phase difference and the second phase difference instead of the first phase difference and the second phase difference. Alternatively, the memory circuit may store the output of the flip flop group instead of the first phase difference and the second phase difference. In this case, the normalization circuit may compute the difference between the previous first phase difference and the previous second phase difference from the output of the flip flop group stored in the memory circuit.

The normalization circuit may be switched, according to a given mode switching signal, between a first operation mode in which the cycle of the first signal is computed from the difference between the previous first phase difference and the previous second phase difference and the difference between the first phase difference and the second phase difference which are currently detected by the edge detector and a second operation mode in which the cycle of the first signal is computed by doubling the difference between the first phase difference and the second phase difference which are detected by the edge detector. In this case, the example frequency synthesizer may include a lock detector configured to detect a locked state of the frequency synthesizer to give an instruction to the digital phase difference detector to switch between the modes.

With this configuration, the operation modes of the digital phase difference detector can accordingly be switched. Thus, for example, depending on whether the frequency of the first signal is variable or stable, the phase difference between the first signal and the second signal can be detected in a more suitable operation mode.

### BRIEF DESCRIPTION OF THE DRAWINGS

FIG. 1 is a view illustrating a configuration of a digital phase difference detector according to an embodiment of the present invention.

FIG. 2 is a timing diagram of various signals for phase difference detection.

FIG. 3 is a timing diagram illustrating various phase differences between two signals.

FIG. 4 is a view illustrating a configuration of a digital phase difference detector according to a variation.

FIG. 5 is a view illustrating a configuration of a digital phase difference detector according to another variation.

FIG. 6 is a view illustrating a configuration of a digital phase difference detector according to still another variation.

FIG. 7 is a view illustrating a configuration of a frequency synthesizer according to an embodiment of the present invention.

FIG. 8 is a view illustrating a configuration of a frequency synthesizer according to another embodiment of the present invention.

FIG. 9 is another timing diagram illustrating various phase differences between two signals.

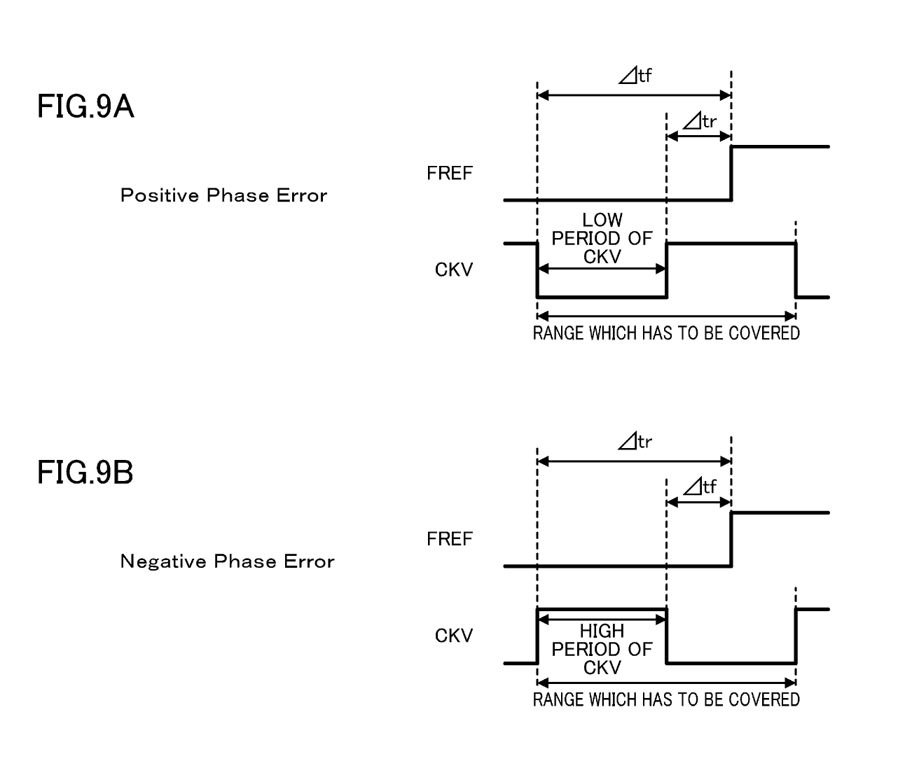

FIG. 10 is still another timing diagram illustrating various phase differences between two signals.

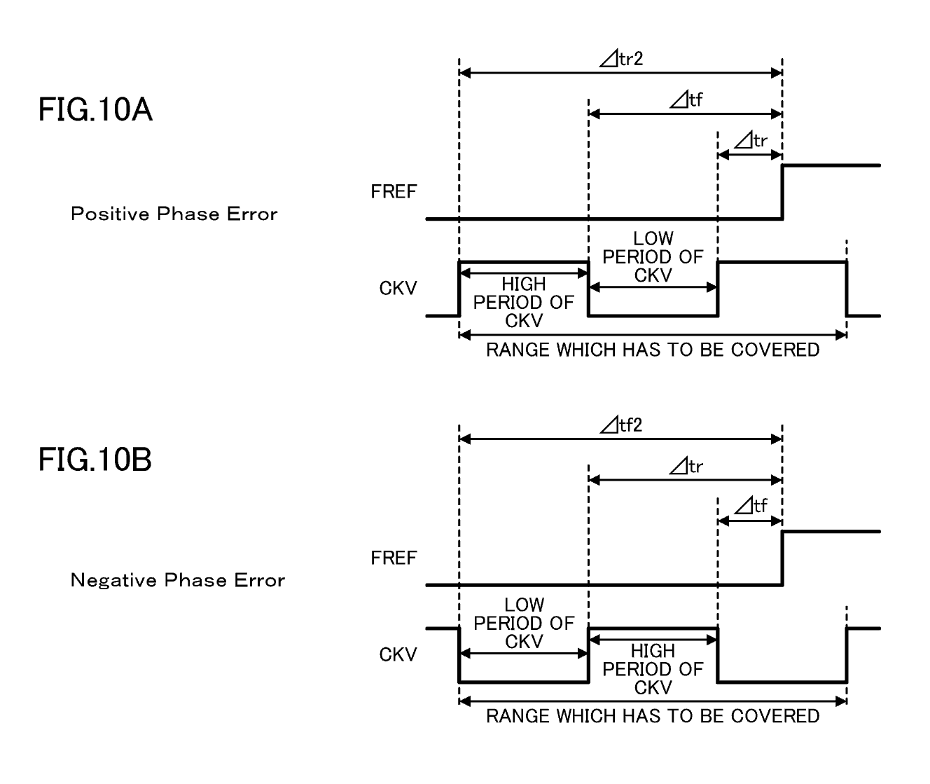

### DETAILED DESCRIPTION

(Embodiment of Digital Phase Detector)

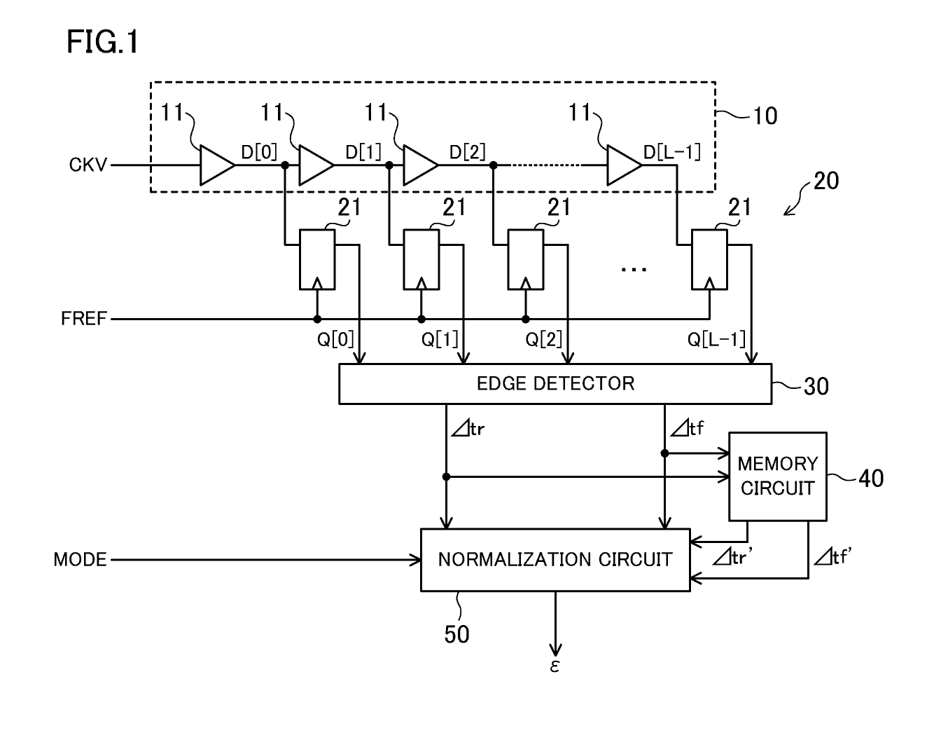

FIG. 1 illustrates a configuration of a digital phase difference detector according to an embodiment of the present invention. A delay circuit 10 includes cascaded delay elements 11 which are composed of, for example, buffer circuits. CKV input to the delay circuit 10 is cumulatively delayed as it passes through the delay elements 11, and is output as signals D[0]-D[L−1] having respective delay amounts. D[0]-D[L−1] are respectively input to flip flops 21 included in a flip flop group 20. Each flip flop 21 latches the input signal at the rise of FREF. From an output of the flip flop group 20, an edge detector 30 detects a phase difference Δtr between the rise of CKV and the rise of FREF, and a phase difference Δtf between the fall of CKV and the rise of FREF.

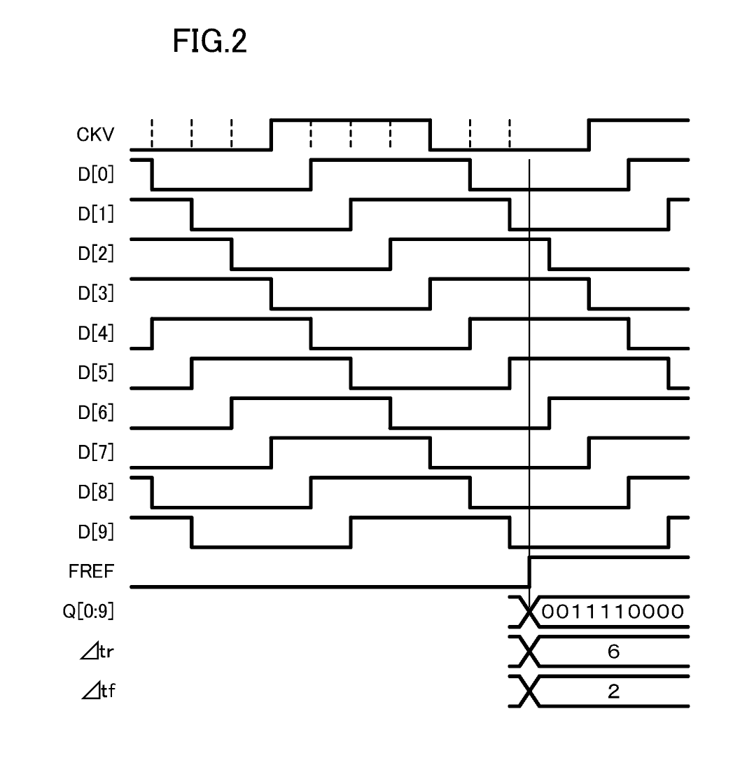

FIG. 2 is a timing diagram of various signals of the digital phase difference detector according to the present embodiment. Note that L=10. D[0]-D[L−1] are latched at the rise of FREF. An output Q[0:9] of the flip flop group 20 is, for example, “0011110000” in binary notation. Δtr is the sum of a sequence of “0” and a sequence of “1” starting from Q[0], and thus is “6.” Δtf is a sequence of “0” starting from Q[0], and thus is “2.” As described above, Δtr and Δtf are converted and quantized correspondingly to the number of stages of the delay elements 11.

Referring back to FIG. 1, a memory circuit 40 stores Δtr and Δtf. More specifically, the memory circuit 40 updates its memory at a timing at which ε is computed in a normalization circuit 50 which will be described later.

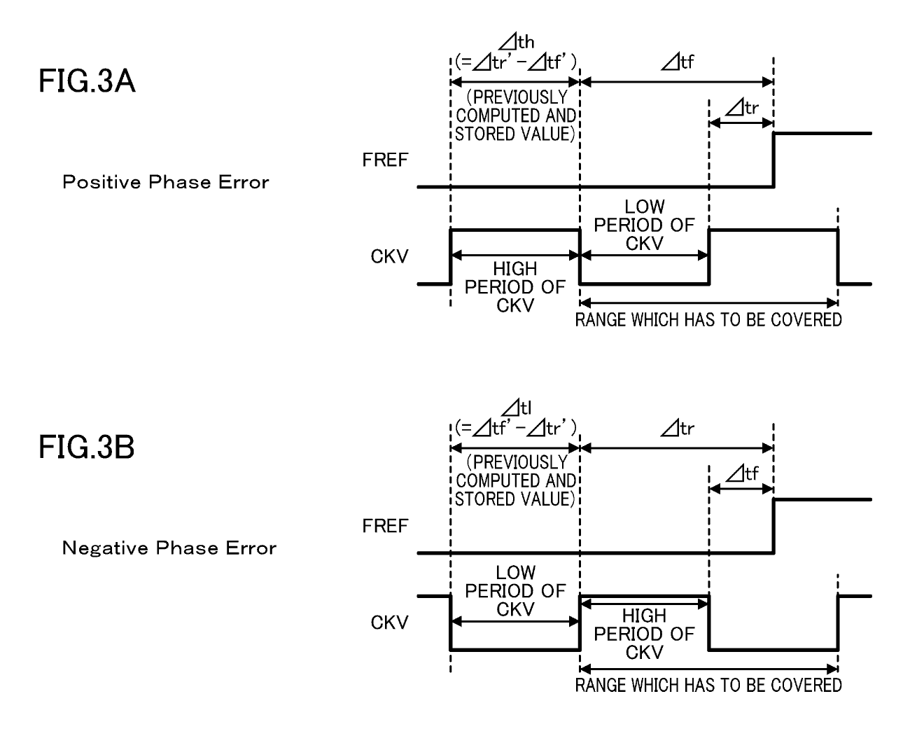

The normalization circuit 50 computes ε from Δtr and Δtf, and a previous Δtr (referred to as Δtr′) and a previous Δtf (referred to as Δtf) which have been stored in the memory circuit 40. The computation of ε is as follows. In the case of a positive phase error (see FIG. 3A), ε=Δtr/(Δtf−Δtr+Δth), and in the case of a negative phase error (see FIG. 3B), ε=Δtr/(Δtr−Δtf+Δt1), where Δth=Δtr′−Δtf, and Δt1=Δtf−Δtr′. That is, in the case of the positive phase error, a low period of CKV is computed from Δtr and Δtf which are detected by the edge detector 30, a high period of CKV is computed from Δtr′ and Δtf′ stored in the memory circuit 40 in a previous negative phase error, and the cycle of CKV is computed by adding the low period to the high period. By contrast, in the case of the negative phase error, the high period of CKV is computed from Δtr and Δtf which are detected by the edge detector 30, the low period of CKV is computed from Δtr′ and Δtf which are stored in the memory circuit 40 in a previous positive phase error, and the cycle of CKV is computed by adding the high period to the low period.

As described above, in the present embodiment, since the high period or the low period of CKV is directly detected, the maximum delay amount of the delay circuit 10 may be one cycle of CKV. Thus, the number of stages of the delay elements 11 included in the delay circuit 10 can be limited to a minimum needed number, and the circuit area and power consumption can be reduced. On the other hand, in order to compute the cycle of CKV, the high period or the low period which is directly detected is not doubled, but the high period or the low period which has been previously directly detected is added to the low period or the high period which is currently directly detected, so that it is possible to achieve detection precision equal to the precision of when the cycle of CKV is directly detected. That is, the digital phase difference detector according to the present embodiment can compute highly precise ε with its circuit area and power consumption being reduced.

Note that in the principle of operation of the normalization circuit 50, the cycle of CKV is computed always after a delay of one cycle, and thus, for example, in a state in which the frequency of CKV is varying, such as during frequency pull-in operation of a PLL in the use of the digital phase difference detector for phase comparison of the frequency synthesizer, the error in ε may contrarily increase if the cycle of CKV is directly detected. Therefore, in such a case, it is preferable to double the high period or the low period of CKV to compute the cycle of CKV, as is conventionally done. Thus, as illustrated in FIG. 1, according to a mode switching signal MODE, the normalization circuit 50 may be switched between a mode in which one cycle of CKV is directly detected and a mode in which the high period or the low period of CKV is doubled. With this configuration, ε can be computed by a suitable method depending on a state of input signals.

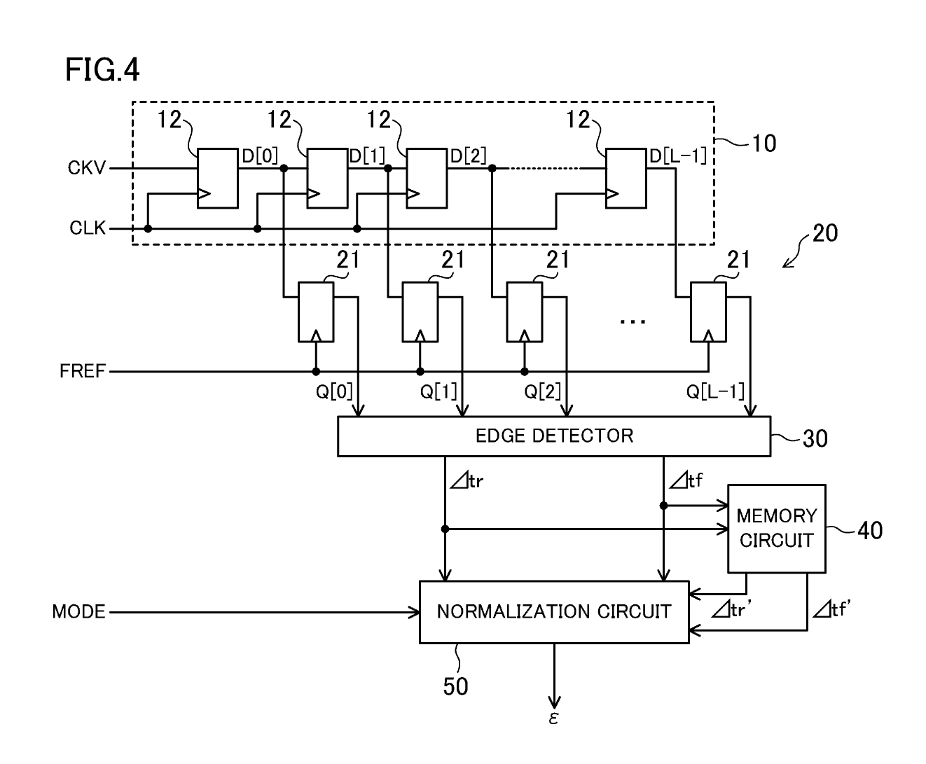

Alternatively, as illustrated in FIG. 4, the delay circuit 10 may be a shift register including cascaded flip flops 12. In this case, signals D[0]-D[L−1] having respective delay amounts each corresponding to the integral multiple of the cycle of an operation clock signal CLK input to each flip flop 12 are generated. In the shift register, both the rise and the fall of CKV are delayed by the cycle of CLK, and thus are less susceptible to the influence of the difference in propagation delay characteristics compared to the case of using the delay elements 11 as illustrated in FIG. 1.

Alternatively, the edge detector 30 may detect Δtr and Δtf with reference to the fall of FREF. That is, a phase difference between the rise of CKV and the fall of FREF may be detected as Δtr, and a phase difference between the fall of CKV and the fall of FREF may be detected as Δtf. In this case, ε represents the ratio of a fall phase difference between FREF and CKV to the cycle of CKV, that is, ε may be defined as: ε=(fall phase difference between FREF and CKV)/(cycle of CKV).

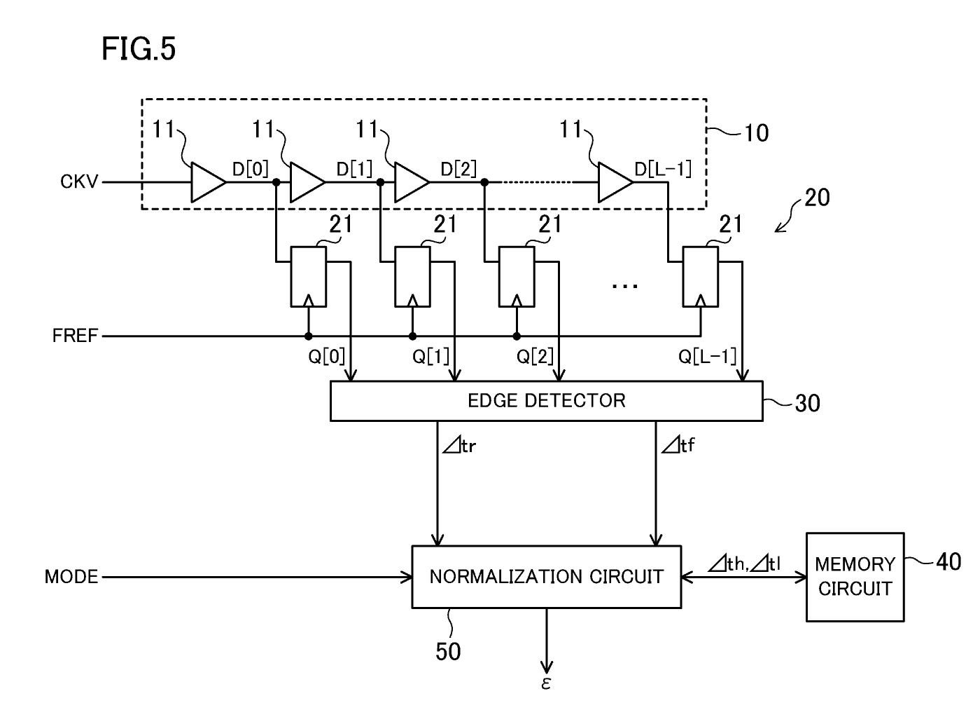

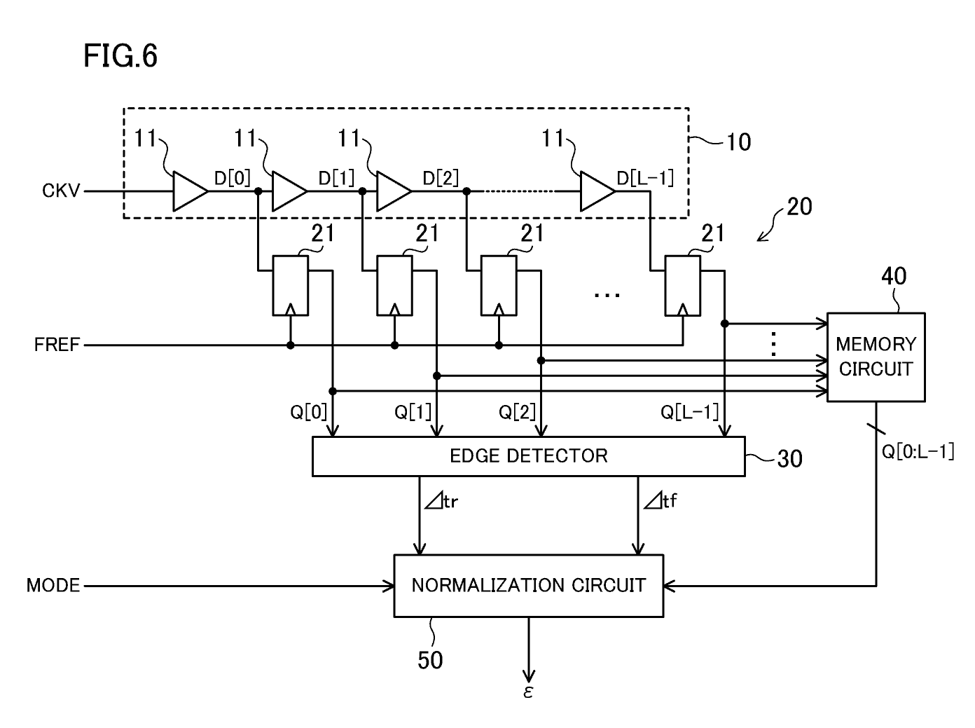

Other than the variation illustrated in FIG. 4, the following variation is possible. For example, as illustrated in FIG. 5, the memory circuit 40 may store Δth and Δt1 which are computed in the normalization circuit 50. In this case, the normalization circuit 50 reads a previous Δth in the case of the positive error phase, and a previous Δt1 in the case of the negative error phase from the memory circuit 40 to compute ε. Alternatively, as illustrated in FIG. 6, the memory circuit 40 may store an output Q[0:L−1] of the flip flop group 20. In this case, the normalization circuit 50 reads a previous Q[0:L−1] from the memory circuit 40 to compute a previous Δtr and a previous Δtf, and further computes a previous Δth in the case of the positive error phase and a previous Δt1 in the case of the negative error phase to compute ε.

(First Embodiment of Frequency Synthesizer)

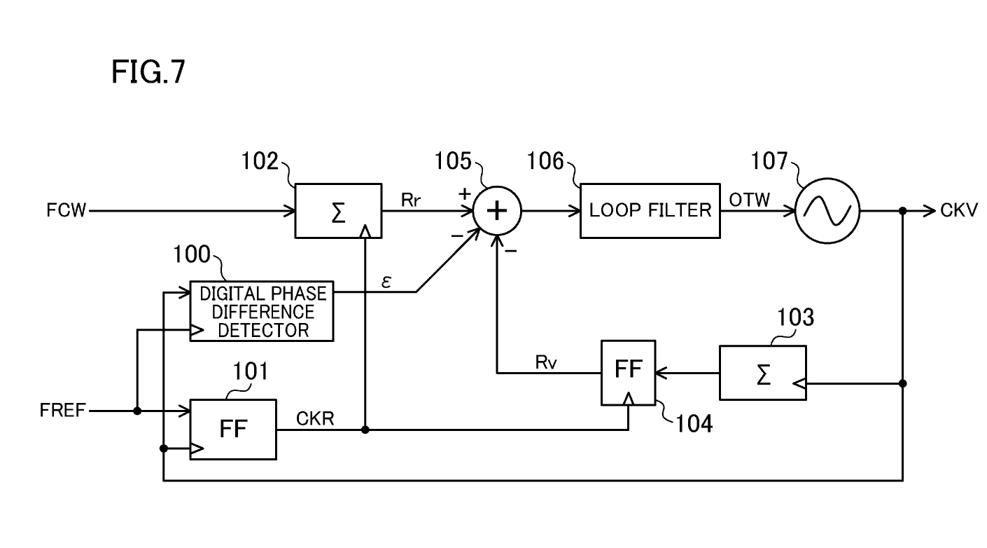

FIG. 7 illustrates a configuration of a frequency synthesizer according to an embodiment of the present invention. The frequency synthesizer is an all-digital frequency synthesizer including a digital phase difference detector 100 according to the embodiment described above. The oscillation frequency is specified by a frequency command word (hereinafter referred to as FCW) in which a value of an integer part and a value of a fraction part are each included. When the frequency of the reference frequency signal FREF is denoted by fREF, and the frequency of the oscillation frequency signal CKV is denoted by fCKV, fCKV=FCW*fREF.

In the frequency synthesizer, the digital phase difference detector 100 detects a phase difference between CKV and FREF as described above to compute a normalized phase difference ε. A flip flop 101 generates an operation clock signal CKR by retiming FREF by CKV. A counter circuit 102 performs the addition of FCW in a cumulative manner at the rise of CKR to generate Rr. A counter circuit 103 increases its count value by 1 at each rise of CKV. A flip flop 104 generates Rv by retiming the count value of the counter circuit 103 by CKR. An adder 105 performs the subtraction Rr−Rv−ε. A loop filter 106 generates an oscillator tuning word (hereinafter referred to as OTW) in digital value based on an output of the adder 105. According to OTW, a digitally controlled oscillator 107 controls the number of varactors (not shown) which are turned on/off, thereby generating CKV.

When the frequency synthesizer is in a locked state, Rr increases by a numeric value represented by FCW at each cycle of CKR, whereas Rv increases by a numeric value corresponding to fCKV/fCKR at each cycle of CKR. Here, CKR is a signal obtained by retiming FREF by CKV, and thus the fCKR is equal to fREF, so that the increment of Rv is equal to fCKV/fREF. Moreover, since fCKV=FCW*fREF, the increment of Rv is equal to FCW. That is, the increment of Rr is equal to the increment of Rv. As described above, when the frequency synthesizer is in the locked state, the increments of Rr and Rv at each rise of CKR are equal to each other, and thus the output of the adder 105 is constant, so that OTW is also a constant value.

However, FCW is a value including the integer part and the fraction part, whereas Rv is an integer value including no fraction part. This is because a value less than “1” from the rise of CKV to the rise of FREF cannot be counted by the counter circuit 103. Thus, in phase comparison using only Rr and Rv, the fraction part of FCW is not taken into consideration, and thus the degree of precision of the phase comparison is reduced, which deteriorates the quality of an output signal of a PLL. For this reason, as a difference representing a value less than “1” which cannot be represented by Rv, ε generated by the digital phase difference detector 100 is input to the adder 105, which enables precise phase comparison in which the fraction part of FCW is also taken into consideration, thereby improving the quality of the output signal of the PLL.

As described above, the digital phase difference detector 100 has a small circuit area and reduced power consumption, and is capable of computing a highly precise ε. Thus, also in the frequency synthesizer including the digital phase difference detector 100, the circuit area and power consumption can be reduced, and the precision can be increased.

(Second Embodiment of Frequency Synthesizer)

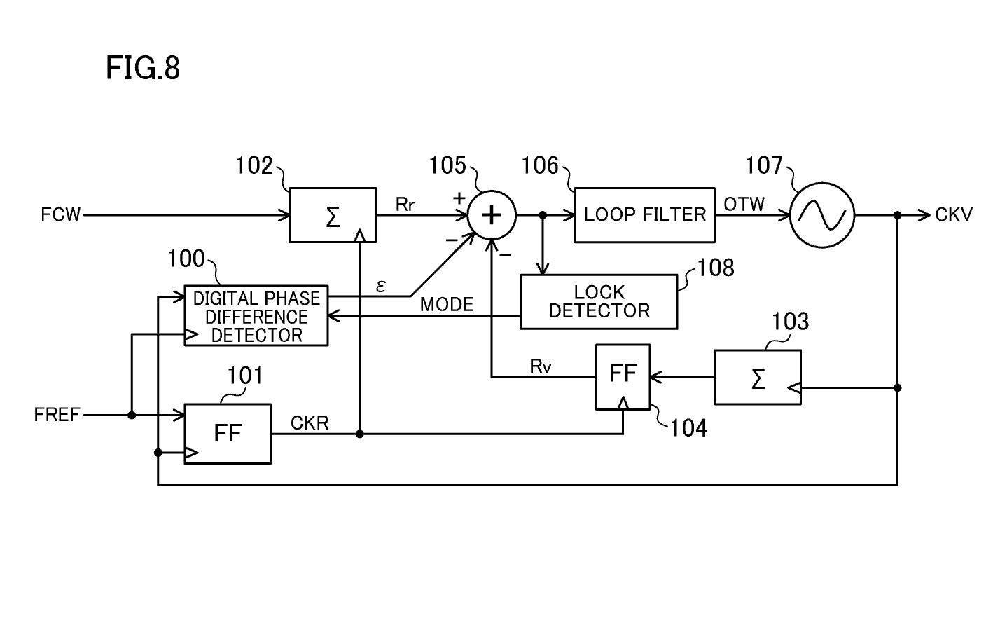

FIG. 8 illustrates a configuration of a frequency synthesizer according to another embodiment of the present invention. The frequency synthesizer can be obtained by adding a lock detector 108 configured to detect a locked state to the frequency synthesizer of FIG. 7. The locked state can be detected when the output of the adder 105 has a constant value, or when OTW has a constant value. The locked state can be detected by other methods than the methods described above.

If the digital phase difference detector 100 operates in the mode of directly detecting one cycle of CKV when the PLL is not locked, such as during frequency pull-in operation of the PLL, the error of ε increases, which increases the frequency pull-in time of the PLL, thereby increasing lockup time. For this reason, based on MODE output from the lock detector 108, the digital phase difference detector 100 operates, in an unlocked state, in the mode of doubling the high period or the low period of CKV to compute one cycle of CKV as is conventionally done, whereas in a locked state, in the mode of directly detecting one cycle of CKV. In this way, it is possible to avoid the increase in lockup time of the PLL.

What is claimed is:

1. A digital phase difference detector for detecting a phase difference between a first signal and a second signal, comprising:
a delay circuit configured to cumulatively delay the first signal to generate signals having respective delay amounts;
a flip flop group configured to latch the signals having the respective delay amounts in synchronization with the second signal;
an edge detector configured to detect, from an output of the flip flop group, a first phase difference between a rise of the first signal and either one of a rise or a fall of the second signal, and a second phase difference between a fall of the first signal and either one of the rise or the fall of the second signal;
a memory circuit configured to store the first phase difference and the second phase difference; and
a normalization circuit configured to compute a cycle of the first signal from a difference between a previous first phase difference and a previous second phase difference which have been stored in the memory circuit and a difference between the first phase difference and the second phase difference which are currently detected by the edge detector to normalize the phase difference between the first signal and the second signal with reference to the cycle.

2. A digital phase difference detector for detecting a phase difference between a first signal and a second signal, comprising:
a delay circuit configured to cumulatively delay the first signal to generate signals having respective delay amounts;
a flip flop group configured to latch the signals having the respective delay amounts in synchronization with the second signal;
an edge detector configured to detect, from an output of the flip flop group, a first phase difference between a rise of the first signal and either one of a rise or a fall of the second signal, and a second phase difference between a fall of the first signal and either one of the rise or the fall of the second signal;
a memory circuit configured to store a difference between the first phase difference and the second phase difference; and
a normalization circuit configured to compute a cycle of the first signal from the difference stored in the memory circuit, the difference being a difference between a previous first phase difference and a previous second phase difference, and a difference between the first phase difference and the second phase difference which are currently detected by the edge detector to normalize the phase difference between the first signal and the second signal with reference to the cycle.

3. A digital phase difference detector for detecting a phase difference between a first signal and a second signal, comprising:
a delay circuit configured to cumulatively delay the first signal to generate signals having delay amounts;
a flip flop group configured to latch the signals having the respective delay amounts in synchronization with the second signal;
a memory circuit configured to store an output of the flip flop group;
an edge detector configured to detect, from an output of the flip flop group, a first phase difference between a rise of the first signal and either one of a rise or a fall of the second signal, and a second phase difference between a fall of the first signal and either one of the rise or the fall of the second signal; and
a normalization circuit configured to compute a difference between a previous first phase difference and a previous second phase difference from the output of the flip flop group stored in the memory circuit, and to compute a cycle of the first signal from the computed difference and a difference between the first phase difference and the second phase difference which are currently detected by the edge detector to normalize the phase difference between the first signal and the second signal with reference to the cycle.

4. The digital phase difference detector of claim 1, wherein
the delay circuit includes a plurality of cascaded delay elements.

5. The digital phase difference detector of claim 2, wherein
the delay circuit includes a plurality of cascaded delay elements.

6. The digital phase difference detector of claim 3, wherein
the delay circuit includes a plurality of cascaded delay elements.

7. The digital phase difference detector of claim 1, wherein
the delay circuit is a shift register.

8. The digital phase difference detector of claim 2, wherein
the delay circuit is a shift register.

9. The digital phase difference detector of claim 3, wherein
the delay circuit is a shift register.

10. The digital phase difference detector of claim 1, wherein
the normalization circuit is switched, according to a given mode switching signal, between
a first operation mode in which the cycle of the first signal is computed from the difference between the previous first phase difference and the previous second phase difference and the difference between the first phase difference and the second phase difference which are currently detected by the edge detector and
a second operation mode in which the cycle of the first signal is computed by doubling the difference between the first phase difference and the second phase difference which are detected by the edge detector.

11. The digital phase difference detector of claim 2, wherein
the normalization circuit is switched, according to a given mode switching signal, between
a first operation mode in which the cycle of the first signal is computed from the difference between the previous first phase difference and the previous second phase difference and the difference between the first phase difference and the second phase difference which are currently detected by the edge detector and
a second operation mode in which the cycle of the first signal is computed by doubling the difference between the first phase difference and the second phase difference which are detected by the edge detector.

12. The digital phase difference detector of claim 3, wherein
the normalization circuit is switched, according to a given mode switching signal, between
a first operation mode in which the cycle of the first signal is computed from the difference between the previous first phase difference and the previous second phase difference and the difference between the first phase difference and the second phase difference which are detected by the edge detector and
a second operation mode in which the cycle of the first signal is computed by doubling the difference between the first phase difference and the second phase difference which are detected by the edge detector.

13. A frequency synthesizer for generating an oscillation frequency signal having a frequency which is a multiple of a frequency command word from a reference frequency signal, the frequency synthesizer comprising:
the digital phase difference detector of claim 1 as a phase difference comparator between the reference frequency signal and the oscillation frequency signal.

14. A frequency synthesizer for generating an oscillation frequency signal having a frequency which is a multiple of a frequency command word from a reference frequency signal, the frequency synthesizer comprising:
the digital phase difference detector of claim 2 as a phase difference comparator between the reference frequency signal and the oscillation frequency signal.

15. A frequency synthesizer for generating an oscillation frequency signal having a frequency which is a multiple of a frequency command word from a reference frequency signal, the frequency synthesizer comprising:
the digital phase difference detector of claim 3 as a phase difference comparator between the reference frequency signal and the oscillation frequency signal.

16. A frequency synthesizer for generating an oscillation frequency signal having a frequency which is a multiple of a frequency command word from a reference frequency signal, the frequency synthesizer comprising:
the digital phase difference detector of claim 10 as a phase difference comparator between the reference frequency signal and the oscillation frequency signal; and
a lock detector configured to detect a locked state of the frequency synthesizer to give an instruction to the digital phase difference detector to switch between the modes.

17. A frequency synthesizer for generating an oscillation frequency signal having a frequency which is a multiple of a frequency command word from a reference frequency signal, the frequency synthesizer comprising:
the digital phase difference detector of claim 11 as a phase difference comparator between the reference frequency signal and the oscillation frequency signal; and
a lock detector configured to detect a locked state of the frequency synthesizer to give an instruction to the digital phase difference detector to switch between the modes.

18. A frequency synthesizer for generating an oscillation frequency signal having a frequency which is a multiple of a frequency command word from a reference frequency signal, the frequency synthesizer comprising:
the digital phase difference detector of claim 12 as a phase difference comparator between the reference frequency signal and the oscillation frequency signal; and
a lock detector configured to detect a locked state of the frequency synthesizer to give an instruction to the digital phase difference detector to switch the between the modes.
